(19) United States
(12) Patent Application Publication
(10) Pub. No.: US 2024/0196632 A1
(43) Pub. Date: Jun. 13, 2024

(54) SEMICONDUCTOR COMPONENTS, FABRICATION METHODS THEREOF AND MEMORY SYSTEMS

(71) Applicant: Yangtze Memory Technologies Co., Ltd., Wuhan (CN)

(72) Inventors: Sheng Peng, Wuhan (CN); Zhiyong Lu, Wuhan (CN); Wenbo Zhang, Wuhan (CN); Xiaoming Mao, Wuhan (CN); Zhaohui Cheng, Wuhan (CN); Jing Gao, Wuhan (CN); Lei Xue, Wuhan (CN)

(21) Appl. No.: 18/148,849

(22) Filed: Dec. 30, 2022

(30) Foreign Application Priority Data
Dec. 9, 2022 (CN) 202211577764.8

(51) Int. Cl. H10B 80/00

(52) U.S. Cl. CPC H10B 80/00

(57) ABSTRACT

Semiconductor components, fabrication methods thereof and memory systems. A fabrication method includes performing trap repairing on a first wafer at a first temperature, the first wafer including memory cells; bonding the first wafer with a second wafer to form a semiconductor component, the second wafer including a device layer; and repairing the semiconductor component at a second temperature lower than the first temperature.

### CROSS REFERENCE TO Related Disclosures

This disclosure claims priority to and the benefit of Chinese Patent Application No. 202211577764.8, filed on Dec. 9, 2022, which is hereby incorporated by reference in its entirety.

### TECHNICAL FIELD

The present disclosure relates to the field of semiconductor fabrication, and more particularly to semiconductor components, methods of fabricating semiconductor devices and memory systems.

### BACKGROUND

In a semiconductor memory, dangling bonds having nonbonding orbitals may be generated at the interface between a polysilicon film and an insulating layer. The dangling bonds are also referred to as “traps”. Existence of the “traps” may cause degradation of memory performance of the semiconductor memory.

### BRIEF DESCRIPTION OF ACCOMPANYING DRAWINGS

Through reading the detailed description of the non-limiting examples made herein with reference to the following figures, other characteristics, purposes and advantages of the teachings of the present disclosure will become apparent, wherein:

FIGS. 1A and 1B are a circuit diagram and a structural diagram of a memory cell string in a memory device, respectively;

FIG. 2 is a flow chart of an example method of fabricating an example semiconductor component in accordance with teachings of the present disclosure;

FIG. 3 is a schematic diagram of a first example implementation of a wafer structured in accordance with teachings of the present disclosure;

FIG. 4 is a partially enlarged diagram of portion A of FIG. 3;

FIG. 5 is a flow chart of an example implementation of block S110 in accordance with teachings of the present disclosure;

FIGS. 6 and 7 are process diagrams of associated with a first implementation of block S110;

FIGS. 8 and 9 are process diagrams associated with a second implementation of block S110;

FIGS. 10 to 12 are process diagrams associated with example implementations of block S120 in accordance with teachings of the present disclosure;

FIG. 13 is a diagram comparing the results of reliability tests performed on two semiconductor components;

FIGS. 14A and 14B are diagrams comparing the results of high gate voltage stress tests performed on two semiconductor components using different voltages;

FIGS. 15 to 17 are process diagrams and a flow chart of example implementations of block S130 in accordance with teachings of the present disclosure;

FIGS. 18 to 20 are partial cross-sectional diagrams of an example implementation of a semiconductor component constructed in accordance with teachings of the present disclosure; and

FIG. 21 is a structural diagram of an example implementation of a memory system in accordance with teachings of the present disclosure.

### DETAILED DESCRIPTION

For better understanding of the present disclosure, various aspects of the disclosure will be described in more detail with reference to the accompanying drawings. It is to be appreciated that the following detailed description is for the purpose of explaining example implementations of the present disclosure and will in no way limit the scope of the present disclosure. Throughout the specification, identical reference numerals refer to identical elements. The expression “and/or” covers any and all combinations of one or more of the listed items that are associated.

It is to be noted that, throughout this specification, expressions such as “first”, “second”, “third” and the like are only used to distinguish one feature from another, and do not imply any limitation for any feature and to not limit any feature to any specific order.

In the figures, thicknesses, dimensions and shapes of components have been somewhat adjusted for easy illustration. The figures are only examples and not strictly drawn to scale. As used herein, the terms “approximate”, “about” and the like indicate approximation instead of degrees and are intended to cover inherent variations in measurement values, manufacturing variances, and/or calculated values, which will be appreciated by those of ordinary skill in the art.

Moreover, in this specification, the terms “on”, “over” or “above” are intended to be interpreted in the broadest manner such that, when one part is described to be “on”, “over” or “above” a second part, “on” not only means “directly on” the second part but also covers “indirectly on, over and/or above” with an intermediate feature or a layer therebetween, Furthermore, “over” or “above” do not take the direction of gravity as an absolute reference unless expressly indicated otherwise. Moreover, when a first element is said to be “over” or “above” a second element, there may be a third element between the first and second elements or there may be no intermediate feature or layer between the first and second elements (i.e., the first element may or may not be directly on the second element while still satisfying the definitions of “on”, “over” and/or “above”).

As used herein, expressions such as “include”, “comprise”, “have” and/or “contain” are not close ended, but instead are open ended terms, (i.e. they indicate existence of the stated feature, element and/or component, but do not exclude existence of one or more additional features, elements, components, multiple instances of the stated feature, multiple instances of the stated element, multiple instances of the stated component, and/or any combinations thereof). Furthermore, when the expression such as “at least one of” precedes a list of features, it modifies all the listed features instead of any individual ones. Furthermore, as used in the description of an implementation of the present disclosure, the term “may” is used to indicate “one or more implementations of the present disclosure”. Also, the term “exemplary” means an example or illustration, not necessarily the best example or illustration.

All the terms (including engineering terms and scientific and technical terms) used herein have the same meanings as those commonly understood by those of ordinary skill in the art, unless otherwise specified. It is also to be appreciated that the terms defined in common dictionaries should be interpreted to have the meanings consistent with their contexts in pertinent arts and should not be interpreted too ideally or formally, unless otherwise specified explicitly in the disclosure.

It is to be noted that examples of the present disclosure and/or the features/subparts thereof may be combined where there are no conflicts. Furthermore, specific blocks contained in a method described in the disclosure may not necessarily be performed in the described order and instead may be performed in any other order or in parallel, unless there is an explicit definition or any conflict with the context. The disclosure will be described in detail hereafter in connection with examples with reference to accompanying drawings.

Moreover, as used in the present disclosure, when the terms “connect” “couple” and/or variants thereof are used herein, it may indicate direct or indirect contact between corresponding components, unless it is otherwise defined or exact meaning can be derived from its context.

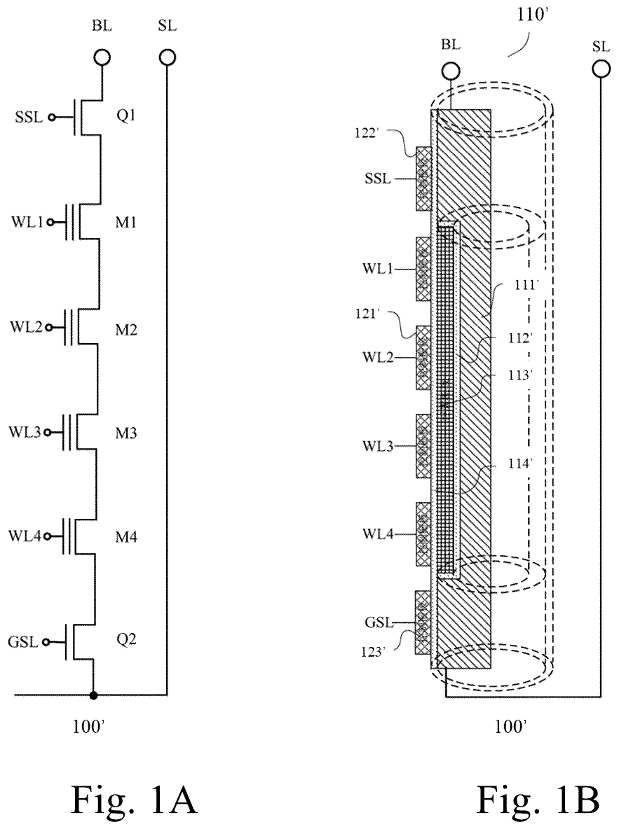

FIG. 1A is a circuit diagram of a memory cell string 100′ applicable to a memory device. FIG. 1B is a structural diagram of the memory cell string 100′. It is to be noted that the structure shown in FIG. 1B is only an example and has no limitation on the structure of the memory cell string 100′. In this example, the case in which the memory cell string 100′ includes 4 memory cells is illustrated. It is understood that the memory cell string 100′ may include any number of memory cells, for example, 32, 64, etc.

As shown in FIG. 1A, the first end of the memory cell string 100′ is connected to a bit line BL and the second end is connected to a source line SL. The memory cell string 100′ includes a plurality of transistors connected in series between the first end and the second end. The plurality of transistors include a first select transistor Q1, memory transistors M1 to M4 and a second select transistor Q2. The gate of the first select transistor Q1 is connected to a string select line SSL and the gate of the second select transistor Q2 is connected to a ground select line GSL. The gates of the memory transistors M1 to M4 are connected to word lines WL1 to WL4 respectively.

As shown in FIG. 1B, the first select transistor Q1 and the second select transistor Q2 of the memory cell string 100′ includes gate conductors 122′ and 123′ respectively, and each of the memory transistors M1 to M4 includes a gate conductor 121′. The order in which the gate conductors 121′, 122′ and 123′ are stacked is consistent with the order in which the transistors of the memory cell string 100′ are stacked and adjacent gate conductors are separated from each other with interlayer insulating layers, so that a gate stack structure is formed. The memory cell string 100′ further includes a channel pillar 110′. The channel pillar 110′ penetrates the gate stack structure. In the middle portion of the channel pillar 110′, a tunneling dielectric layer 112′, a charge storage layer 113′ and a blocking dielectric layer 114′ are disposed between the gate conductors 121′ and the channel layer 111′, so that the memory transistors M1 to M4 are formed. At both ends of the channel pillar 110′, the blocking dielectric layer 114′ is disposed between the gate conductors 122′, 123′ and the channel layer 111′, so that the first select transistor Q1 and the second select transistor Q2 are formed.

In this example, the channel layer 111′ is, for example, composed of doped polysilicon. In this example, the tunneling dielectric layer 112′ and the blocking dielectric layer 114′ are each composed of oxide such as, for example, silicon oxide. In this example, the charge storage layer 113′ is composed of an insulating layer including quantum dots or nanocrystal such as, for example, silicon nitride including particles of metal or semiconductor. In this example, the gate conductors 121′, 122′ and 123′ are composed of metal such as, for example, tungsten. The channel layer 111′ is used to provide channel regions of the select transistors and the memory transistors, and has the same doping type as that of the select transistors and the memory transistors. For example, for the select transistors and the memory transistors of N type, the channel layer 111′ may be N-type doped polysilicon.

In this example, the core of the channel pillar 110′ is the channel layer 111′, The tunneling dielectric layer 112′, the charge storage layer 113′ and the blocking dielectric layer 114′ form a stack structure surrounding the sidewall of the core. In an alternative example, the core of the channel pillar 110′ is an additional insulating layer, and the channel layer 111′, the tunneling dielectric layer 112′, the charge storage layer 113′ and the blocking dielectric layer 114′ form the stack structure surrounding the sidewall of the core.

In this example, the first select transistor Q1, the second select transistor Q2 and the memory transistors M1 to M4 use the channel layer 111′ and the blocking dielectric layer 114′ in common. In the channel pillar 110′, the channel layer 111′ provides source/drain regions and channel regions of a plurality of transistors. In an alternative example, the semiconductor layers and the blocking dielectric layers of the first select transistor Q1 and the second select transistor Q2 and those of the memory transistors M1 to M4 may be formed respectively in separate steps.

In a write operation, the memory cell string 100′ writes data into the selected ones of the memory transistors M1 to M4 using the Fowler-Nordheim (FN) tunneling effect. With the memory transistor M2 taken as an example, while the source line SL is grounded, the ground select line GSL is biased to a voltage of about zero volt, such that the second select transistor Q2 corresponding to the ground select line GSL is turned off, and the string select line SSL is biased to a high voltage VDD, such that the first select transistor Q1 corresponding to the string select line SSL is turned on. The bit line is grounded. The word line WL2 is biased to a program voltage VPG, for example, about 20V. The other word lines are each biased to a low voltage VPS1. Since only the word line voltage for the selected memory transistor M2 is higher than the tunneling voltage, the electrons in the channel region of the memory transistor M2 enter the charge storage layer 113′ via the tunneling dielectric layer 112′ to store the charges converted from the data in the charge storage layer 113′ of the memory transistor M2.

In a read operation, the memory cell string 100′ determines the quantity of charges in the charge storage layer 113′ according to the on state of the selected one of the memory transistors M1 to M4, so as to obtain the data represented by the quantity of charges. With the memory transistor M2 taken as an example, the word line WL2 is biased to a read voltage VRD and the other word lines are each biased to a high voltage VPS2. The on state of the memory transistor M2 is associated with its threshold voltage, (i.e. the quantity of charges in the charge storage layer 113′), so that the data value can be determined according to the on state of the memory transistor M2. The memory transistors M1, M3 and M4 are always in the on state, and thus, the on state of the memory cell string 100′ is dependent on the on state of the memory transistor M2. The control circuit determines the on state of the memory transistor M2 according to the electrical signals detected from the bit line BL and the source line SL to obtain the data stored in the memory transistor M2.

There is a great amount of Si dangling bonds at the grain boundary in the channel layer 111′ and there is a great amount of vacancies or voids in the SiON layers of the tunneling dielectric layer 112′ and the charge storage layer 113′. The dangling bonds in the channel layer 111′ and the vacancies or voids in the tunneling dielectric layer 112′ and the charge storage layer 113′ form traps in the memory cell string 100′. The traps not only influence the degree of convergence in threshold voltage magnitude during read operations, but also influence the degree of variation in threshold voltage when the memory transistors are at high temperatures and low temperatures, and thus influence the read margin at the high temperatures and low temperatures. Moreover, due to different bonding environments, the formed trap levels may be deep or shallow. Traps of shallow levels may cause the electrons that have already been in the tunneling dielectric layer 112′ to tunnel with assistance of traps, and the traps of shallow levels in the tunneling dielectric layer 112′ may make the electrons that have already been programmed more liable to diffuse in the charge storage layer 113′ or tunnel through the tunneling dielectric layer 112′, lowering the reliability of the memory transistors.

In order to repair the traps, in related arts, a process of trap repairing is performed after bonding a memory array wafer including the memory cell string 100′ to a CMOS wafer including logic devices and wiring the memory array and the logic devices. Constrained by the requirements for reliability of CMOS devices and by the requirements for connection and wiring of circuits, thermal treatments at temperatures not higher than 450° C. are performed to repair the traps. However, although traps of shallow levels can be repaired and, thus, become traps of deep levels by the trap repairing process when performed at the temperatures to reduce unstable trapping of electrons, at the same time the repairing process may cause some traps of deep levels to instead become traps of shallow levels. For example, the traps of oxygen vacancies are formed in the tunneling dielectric layer 112′, which will undoubtedly constrain the overall performance of the memory device.

In view of these concerns, teachings of this disclosure provide methods of fabricating semiconductor components of superior quality as explained through detailed examples provided below.

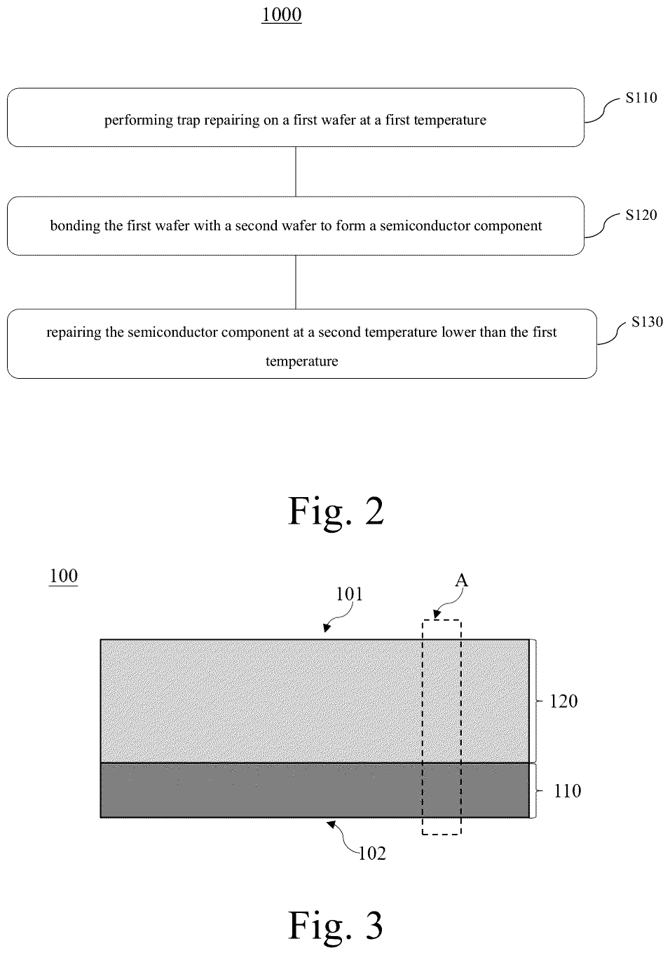

FIG. 2 is a flow chart illustrating an example implementation of a method 1000 of fabricating a semiconductor component 10 structured in accordance with teachings of the present disclosure. As shown in FIG. 2, the fabrication method 1000 includes following operations.

In block S110, a trap repairing is performed on the first wafer at a first temperature, the first wafer including memory cells.

In block S120, the first wafer is bonded with a second wafer to form a semiconductor component, the second wafer including a device layer.

In block S130, the semiconductor component is repaired at a second temperature lower than the first temperature.

In the solution above, before bonding the first wafer with the second wafer, the trap repairing process is performed at a relatively high temperature is used to repair the traps in the memory cells of the first wafer, so that the traps of shallow levels are repaired and become the traps of deep levels. And after bonding the first wafer with the second wafer, the trap repairing process is performed at a relatively low temperature to repair the traps in the semiconductor component, enabling the unstable hydrogen bonds in the traps of shallow levels that have not yet been repaired to break and allow hydrogen gas to escape. By performing the above-described trap repairing processes in two operations, trap repairing of the memory cells in the semiconductor component is improved (e.g., optimized) and performance of the memory cells can be significantly improved (e.g., to a maximum degree) without influencing the reliability of circuits in the device layer.

It is to be understood that the operations shown in the fabrication method 1000 are not exclusive and other operations may be performed before, after or between any one(s) of the shown operations represented by the blocks of the flow charts. In addition, some of the operations may be performed simultaneously or in an order different from the one shown in FIG. 2. The blocks S110 to S130 described above will be more detailed hereafter in connection with FIGS. 2 to 20.

### Block S110

The first wafer 100 includes a memory array having a plurality of memory cells. FIG. 3 is a partial cross-sectional diagram of the structure of the first wafer 100. As shown in FIG. 3, the first wafer 100 includes a substrate 110 and a stack structure 120 formed on the first substrate 110.

The first substrate 110 may be used to support the device structures thereon and may include at least one of single crystal silicon (Si), single crystal germanium (Ge), III-V compound semiconductor, II-VI compound semiconductor and/or any other semiconductor material without limitation. In some examples, the first substrate 110 is a composite structure and includes a plurality of layer fabricated sequentially with different materials.

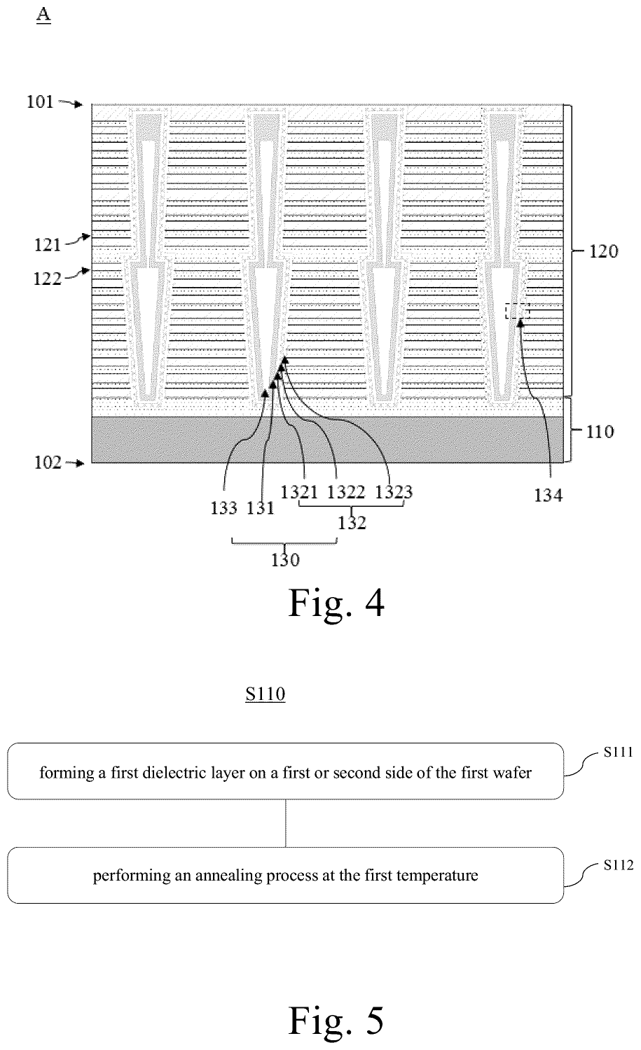

FIG. 4 is a partially enlarged diagram of portion A in FIG. 3. As shown in FIG. 4, the stack structure 120 includes a plurality of alternately stacked insulating layers 121 and gate layers 122. The gate layers 122 include a conductive material such as, for example, any one or combination of tungsten (W), cobalt (Co), copper (Cu), aluminum (Al), doped crystalline silicon or silicide. The insulating layers 121 may include, for example, silicon oxide (SiOX). The number of layers of the stack structure 120 is not limited to that shown in the figure, and can be different to suit the requirements of the use, for example, 32, 64, 128 etc. In some examples, the materials for conductor filling, adhesion or blocking may be disposed at the periphery of the gate layers 122.

Referring to FIG. 4 again, the first wafer 100 includes a plurality of memory string channel structures 130 extending through the stack structure 120 into the first substrate 110. The memory string channel structure 130 may roughly have, for example, a profile of cylinder, truncated cone or prism. For example, the memory string channel structure 130 may have its outer wall that includes a memory dielectric layer 132 and a channel layer 131 disposed in this order from outside to inside. In some examples, the memory dielectric layer 132 may include, for example, a charge blocking layer 1323, a charge trapping layer 1322 and a tunneling layer 1321 disposed in this order from outside to inside. The material of the charge blocking layer 1323, the charge trapping layer 1322 and the tunneling layer 1321 may include, for example, silicon oxide, silicon nitride and silicon oxide in this order, and thus form the memory dielectric layer 132 to have an ONO structure. The channel layer 131 may include a semiconductor material, e.g. silicon, such as amorphous silicon, polysilicon or single crystal silicon and/or the like. The memory string channel structure 130 further includes a filling dielectric layer 133 (for example, silicon oxide) surrounded by the channel layer 131.

The gate layers 122 in the stack structure 120 may be formed by performing a “gate replacement” process after forming the memory string channel structures 130. The memory string channel structures 130 may be formed after forming the gate layers 122 or in any other order. Moreover, the “gate replacement” process may use techniques well known in the art and will not be repeated here.

After forming the memory string channel structures 130 and the gate layers 122, each gate layer 122 and the memory string channel structure 130 at the layer form a memory cell 134.

In some implementations, as shown in FIG. 5, block S110 (e.g., performing trap repairing at the first temperature on the above-mentioned first wafer 100 having memory string channel structures 130 formed therein) includes the following operations.

In block S111, a first dielectric layer containing hydrogen bonds is formed on the first or second side of the first wafer, wherein the first side is the side to be bonded with the second wafer and the second side is the other side opposite to the first side.

In block S112, an annealing process is performed at the first temperature to passivate the traps in the memory cells.

Two example implementations are provided for block S110 in the present disclosure, and will be described in detail below respectively.

### Implementation 1

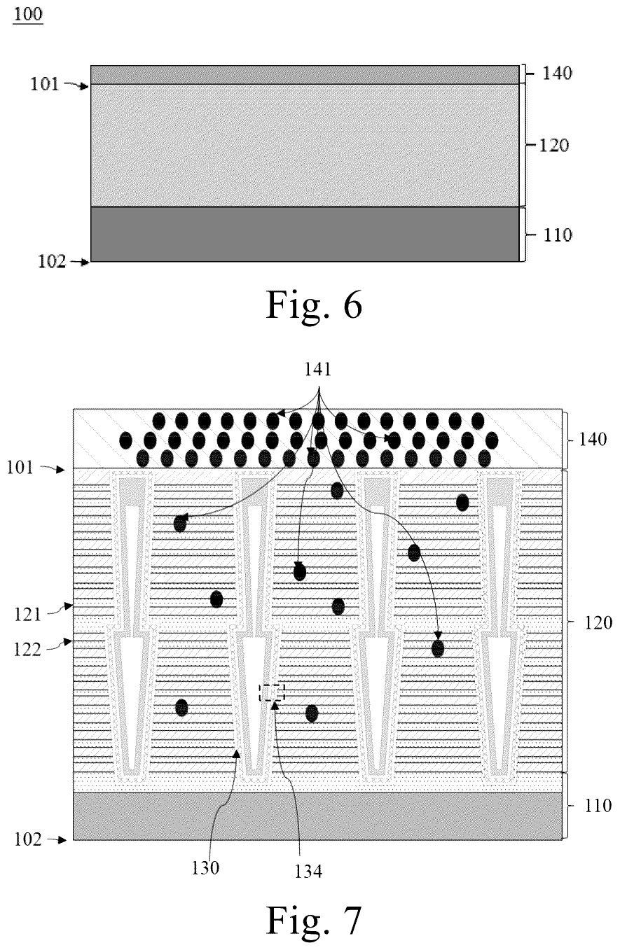

FIGS. 6 and 7 are process diagrams of a first example implementation of block S110.

As shown in FIG. 6, in block S111, a first dielectric layer 140 is formed on the first side 101 of the first wafer 100. The first side 101 of the first wafer 100 refers to the side to be bonded with the second wafer 200 during a subsequent process. In other words, the first side 101 of the first wafer 100 may represent the side of the stack structure 120 away from the first substrate 110.

In some examples, the first dielectric layer 140 may be formed on the surface of the side of the stack structure 120 away from the first substrate 110 using one or more thin film deposition processes. By way of examples, not limitations, the thin film deposition processes may include chemical vapor deposition (CVD), physical vapor deposition (PVD), atomic layer deposition (ALD) and/or any combination thereof. In some examples, the first dielectric layer 140 is a passivation layer rich of hydrogen or deuterium and has a material of at least one of nitride containing hydrogen bonds, polysilicon containing hydrogen bonds and/or carbonitride containing hydrogen bonds.

In block S112, an annealing process is performed at a temperature higher than 450° C. to passivate the traps in the memory cells.

In particular, when the annealing process is performed in this block, the first wafer 100 has not been bonded to the second wafer 200 including peripheral devices, and thus there is no concern about the influence on the CMOS devices and connection and wiring of the circuits caused by too high a temperature at which the annealing process is performed in this block. As an example, the first temperature may be selected from the range of 500° C.-800° C.

During the annealing process performed in this block, a great amount of hydrogen bonds in the first dielectric layer 140 break due to the high temperature, and, thus, a great amount of free hydrogen ions 141 are formed. The free hydrogen ions 141 diffuse into the stack structure 120 under the high temperature, as shown in FIG. 7. Therefore, the great amount of hydrogen ions 141 that have diffused into the stack structure 120 may combine (e.g., fully combine) with the dangling bonds traps in the channel layer 131 and the vacancies or voids traps in the tunneling layer 1321 and the charge trapping layer 1322 to repair these traps.

### Implementation 2

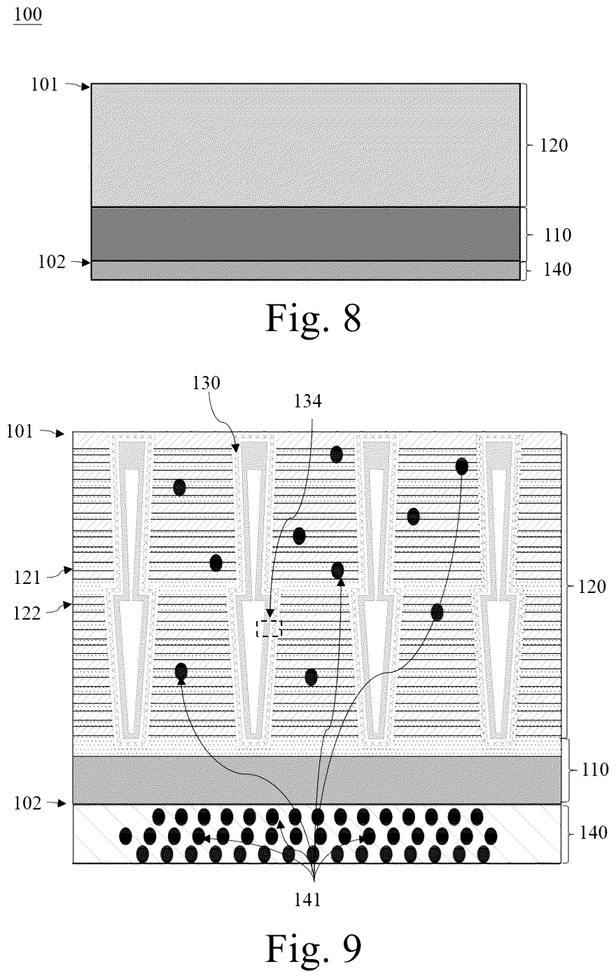

FIGS. 8 and 9 are process diagrams of the second example implementation of block S110.

As shown in FIG. 8, in block S11l, the first dielectric layer 140 is formed on the second side 102 of the first wafer 100. The first side 101 of the first wafer 100 refers to the side to be bonded with the second wafer 200 during a subsequent process, and the second side 102 of the first wafer 100 is the other side opposite to the first side 101. In other words, the second side 102 of the first wafer 100 may represent the side of the first substrate 110 away from the stack structure 120.

In some examples, the first dielectric layer 140 may be formed on the surface of the side of the first substrate 110 away from the stack structure 120 using one or more thin film deposition processes. By way of examples, not limitations, the thin film deposition processes include chemical vapor deposition (CVD), physical vapor deposition (PVD), atomic layer deposition (ALD) and/or any combination thereof. In some examples, the first dielectric layer 140 is a passivation layer rich of hydrogen or deuterium and has a material of at least one of nitride containing hydrogen bonds, polysilicon containing hydrogen bonds and/or carbonitride containing hydrogen bonds.

In block S112, the annealing process is performed at a temperature higher than 450° C. to passivate the traps in the memory cells.

In particular, when the annealing process is performed in this block, the first wafer 100 has not yet been bonded to the second wafer 200 (e.g., to the wafer including peripheral devices), and thus there is no concern about damage to the CMOS devices, connections and/or wiring of the circuits caused by too high a temperature at which the annealing process is performed in this block. As an example, the first temperature may be selected from the range of 500° C.-800° C.

During the annealing process performed in this block, a great amount of hydrogen bonds in the first dielectric layer 140 break under the high temperature, thus forming a great amount of free hydrogen ions 141. The free hydrogen ions 121 diffuse into the stack structure 120 through the substrate 110 under the high temperature, as shown in FIG. 9. Therefore, the great amount of hydrogen ions 141 that have diffused into the stack structure 120 may combine (e.g., fully combine) with the dangling bonds traps in the channel layer 131 and the vacancies or voids traps in the tunneling layer 1321 and the charge trapping layer 1322 to repair these traps.

In the first and second example implementations of Block S111, the thickness of the first dielectric layer 140 formed on the first side 101 or the second side 102 of the first wafer 100 may be in the micrometer order of magnitude, and may, for example, range from 2 μm to 10 μm. The hydrogen bonds in the first dielectric layer 140 may be considered as the source of free hydrogen ions needed to repair the traps in block S112. It is noted that better effect of the above trap repairing will be obtained when the hydrogen content of the first dielectric layer 140 is higher than 1 e21 cm-3.

In the first and second example implementations of Block S112, the annealing process should be performed in a vacuum environment or a protected atmosphere formed by at least one of N2, Ar, He and H2 gases, and may have its duration range from 2 h (hours) to 10 h (hours). In some examples, the duration may range from 2 h to 5 h. For example, when the first temperature is relatively high, the duration of the annealing process may be relatively short, and when the first temperature is relatively low, the duration of the annealing process may be relatively long, so as to balance trap repairing effect and production efficiency.

In some implementations, after performing trap repairing on the first wafer 100 at the first temperature and before repairing the semiconductor component at the second temperature lower than the first temperature, the fabrication method 1000 may further include: removing the first dielectric layer.

As an example, the first dielectric layer 140 may be removed using a wet etching process. In the above-described solution, the first dielectric layer 140 is removed after trap repairing has been performed on the first wafer 100 at the first temperature, and the thickness of the first wafer 100 may be controlled to fall in a reasonable range, and thus controlling a wafer warpage of the first wafer 100.

If the requirement with respect to the wafer warpage of the first wafer 100 has been satisfied, the first dielectric layer 140 may not be removed, or may not be removed completely with a portion of a certain thickness of the first dielectric layer 140 removed, leaving the first dielectric layer 140 with a corresponding thickness.

### Block S120

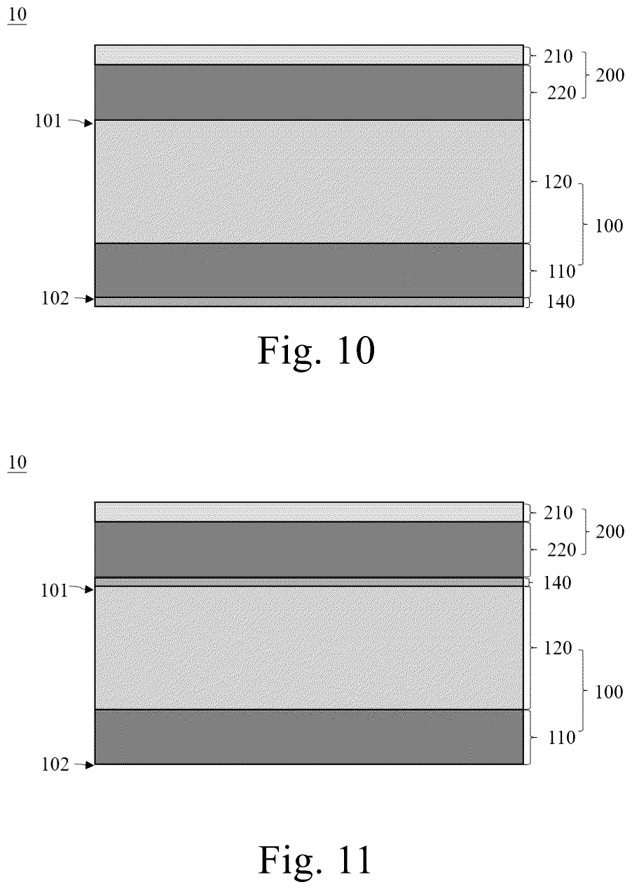

FIGS. 10 to 12 are example process diagrams of corresponding to block S120.

As shown in FIGS. 10 to 12, the second wafer 200 includes a second substrate 210 and a device layer 220 formed on the second substrate 210. The second substrate 210 may be used to support the device structures thereon and include at least one of single crystal silicon (Si), single crystal germanium (Ge), III-V compound semiconductor, II-VI compound semiconductor and/or any other semiconductor material without limitation. The device layer 220 includes, for example, peripheral devices such as transistor devices (CMOS).

Bonding contacts to be bonded with the first wafer 100 are formed on the side of the device layer 220 away from the second substrate 210. Bonding contacts to be bonded with the second wafer 200 are also formed on the first side 101 of the first wafer 100. Thereby, in block S120, the first wafer 100 and the second wafer 200 are bonded together to form a semiconductor component 10.

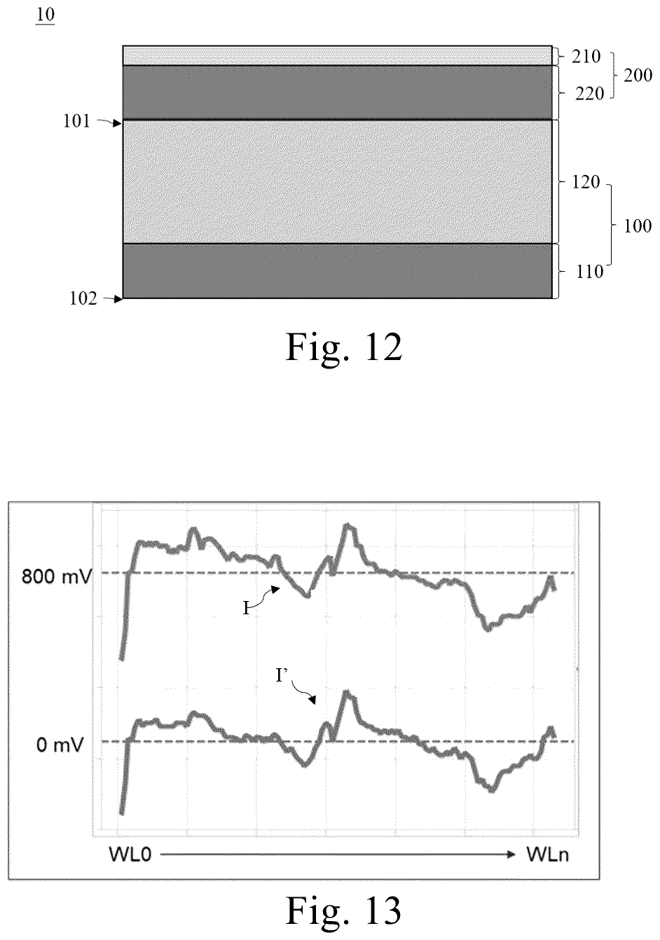

Referring to the semiconductor component 10 shown in FIG. 10, it includes the first wafer 100, the second wafer 200 and the first dielectric layer 140 remaining on the second side 102 of the first wafer 100. Referring to the semiconductor component 10 shown in FIG. 11, it includes the first wafer 100, the second wafer 200 and the first dielectric layer 140 remaining on the first side 101 of the first wafer 100. Referring to the semiconductor component 10 shown in FIG. 12, it includes the first wafer 100 and the second wafer 200.

### Block S130

After bonding the first wafer 100 to the second wafer 200, the semiconductor component 10 is repaired at a second temperature lower than the first temperature to further repair the traps in the memory cells.

In particular, when an annealing process is performed in block S130, the first wafer 100 has already been bonded with the second wafer 200. Thus, the influence of excessive heat on the CMOS devices, connections and wiring of the circuits by the annealing process should be take into account when performing the annealing process of block S130. Therefore, the second temperature should be lower than the first temperature. As an example, the second temperature may be selected from the range of 400° C.-450° C. In block S130, the annealing process should be performed in a vacuum environment or a protected atmosphere formed by at least one of N2, Ar, He and H2 gases, for a duration in the range of 2 h to 10 h. In some examples, the duration may range from 2 h to 5 h. Likewise, when the second temperature is relatively high, the duration of the annealing process may be relatively short, and when the second temperature is relatively low, the duration of the annealing process may be relatively long, so as to balance trap repairing effect and production efficiency.

For block S130, this disclosure provides three example implementations, which will be described in detail below respectively.

### Implementation 1

With continued reference to FIG. 12, if the first dielectric layer 140 formed on the first side 101 or the second side 102 of the first wafer 100 is removed completely after performing the annealing process in block S110, the annealing process in block S130 may be performed on the semiconductor component 10 as shown in FIG. 12 at a temperature between 400° C. and 450° C. without the passivation film.

During the annealing process performed in block S130, unstable hydrogen bonds in the traps of shallow levels that fail to be repaired in block S110 and in the traps of shallow levels formed in block S110 may break to form hydrogen gas which escapes By performing the above-described trap repairing processes in two blocks, the trap repairing of memory cells in the semiconductor component 10 can be improved (e.g., optimized) and performance of the memory cells can be improved (e.g., to the maximum degree) without influencing the reliability of circuits in the device layer 220.

FIG. 13 is a diagram comparing the results of reliability tests performed on two semiconductor components. The curve I in the graph represents the result of the reliability test performed on the semiconductor component fabricated using an example trap treatment process in accordance with teachings of this disclosure, and the curve I′ represents the result of the reliability test performed on a semiconductor component fabricated using a known trap treatment process.

It can be seen from FIG. 13 that the value of Edge Summary (ESUM) of the semiconductor component fabricated using the example trap treatment process in accordance with teachings of this disclosure is increased by 800 mV with respect to that of the semiconductor component fabricated using the known trap treatment process. A relatively large ESUM can guarantee reliability of the semiconductor component, enabling the semiconductor component to satisfy use requirements.

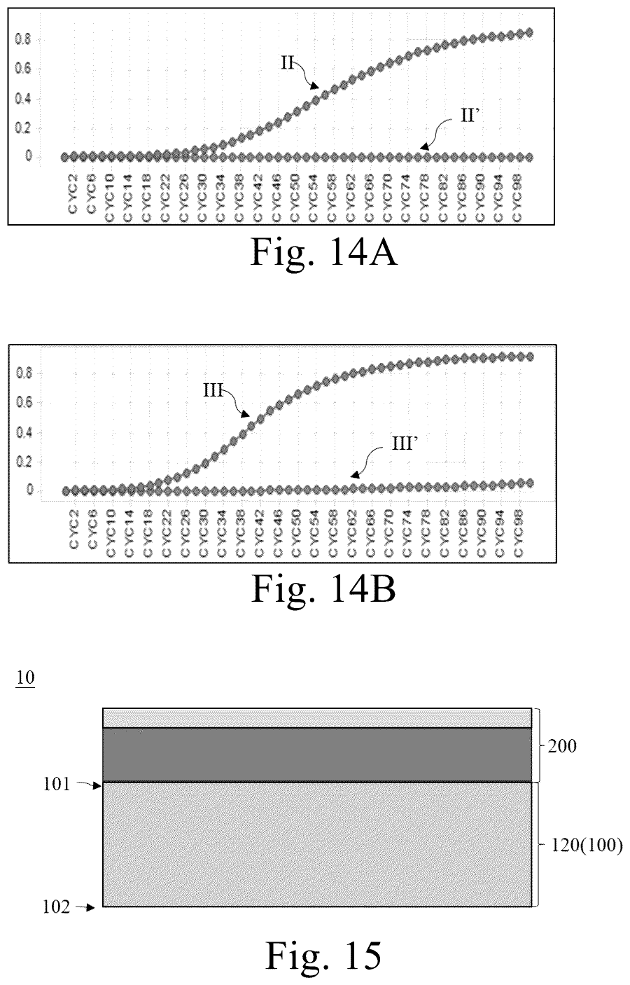

FIG. 14A is a diagram comparing the results of high gate voltage stress tests performed on two semiconductor components using a first voltage. The curve II in the graph represents the result of the high gate voltage stress test performed on the semiconductor component fabricated using an example trap treatment process in accordance with teachings of this disclosure, and the curve II′ represents the result of the high gate voltage stress test performed on a semiconductor component fabricated using a known trap treatment process. FIG. 14B is a diagram comparing the results of high gate voltage stress tests performed on two semiconductor components using a second voltage. The curve III in the graph represents the result of the high gate voltage stress test performed on the semiconductor component fabricated using an example trap treatment process in accordance with teachings of this disclosure, and the curve III′ represents the result of the high gate voltage stress test performed on a semiconductor component fabricated using a known trap treatment process.

As can be seen from FIGS. 14A and 14B, when the high gate voltage stress test is performed on the semiconductor component fabricated using an example trap treatment process in accordance with teachings of this disclosure, with the increasing of times of voltage application (horizontal axis), the failure rate (vertical axis) of the memory cells in the semiconductor component always remain at a level near zero. However, when the high gate voltage stress test is performed on the semiconductor component fabricated using the known trap treatment process, with the increasing of times of voltage application, the failure rate of the memory cells in the semiconductor component increases gradually to reach a level near 1.

It can be seen that, by using an example trap treatment process as disclosed in this disclosure, both reliability and tolerance for high voltages of a semiconductor component can be increased.

### Implementation 2

With continued reference to FIGS. 10 and 11, if a portion of the first dielectric layer 140 is removed after performing the annealing process in block S110, during the annealing process performed in block S130 on the semiconductor component 10 shown in FIG. 10 or 11, the hydrogen bonds left in the remaining portion of the first dielectric layer 140 may break and diffuse into the device layer 220 of the second wafer 200 to repair the traps in the device layer 220. Moreover, during the annealing process, unstable hydrogen bonds in the traps of shallow levels that fail to be repaired in block S110 and in the traps of shallow levels formed in block S110 may break and form escaping hydrogen gas. By performing the above-described trap repairing processes in two operations, the trap repairing of memory cells in the semiconductor component 10 and the trap repairing of the device layer 220 can be improved (e.g., optimized) at the same time and the storage performance of the semiconductor component 10 can be improved (e.g., to the maximum degree) without influencing the reliability of circuits in the device layer 220.

### Implementation 3

Before performing the implementation, the fabrication method 1000 further includes: removing the first substrate 110 of the first wafer 100, as shown in FIG. 15. After the first substrate 110 is removed, the second side 102 of the first wafer 100 refers to the side of the stack structure 120 away from the second wafer 200.

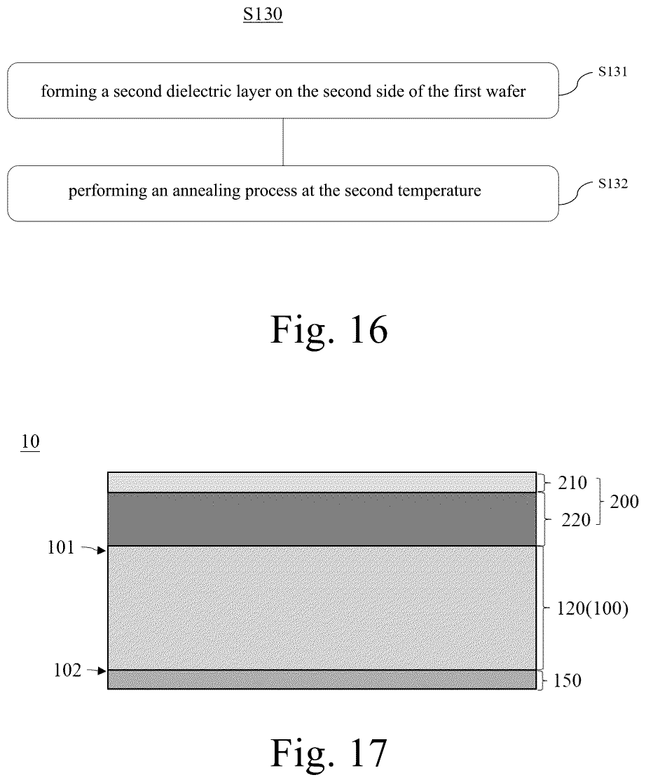

In the implementation, as shown in FIG. 16, block S130 includes the operations described below.

In block S131, a second dielectric layer containing hydrogen bonds is formed on the second side of the first wafer.

In block S132, an annealing process is performed at a second temperature to repair the traps in the semiconductor component.

Referring to FIG. 17, in block S131, a second dielectric layer 150 containing hydrogen bonds is formed on the surface of the side of the stack structure 120 in the first wafer 100 away from the second wafer 200. In some examples, the second dielectric layer 150 may be formed on the surface of the side of the stack structure 120 away from the second wafer 200 using one or more thin film deposition processes. The thin film deposition processes include, without limitation, chemical vapor deposition (CVD), physical vapor deposition (PVD), atomic layer deposition (ALD) and/or any combination thereof. In some examples, the material of the second dielectric layer 150 is at least one of nitride containing hydrogen bonds, polysilicon containing hydrogen bonds and carbonitride containing hydrogen bonds.

It is noted that, although the second dielectric layer 150 contains hydrogen bonds, the content of hydrogen bonds in the second dielectric layer 150 is much lower than that in the first dielectric layer 140.

In block S132, an annealing process is performed on the semiconductor component 10 shown in FIG. 17 at a second temperature lower than 450° C. to make the hydrogen bonds in the second dielectric layer 150 break and diffuse into the device layer 220 of the second wafer 200 to repair the traps in the device layer 220. Moreover, during the annealing process, unstable hydrogen bonds in the traps of shallow levels that fail to be repaired in block S110 and in the traps of shallow levels formed in block S110 may break and escape as hydrogen gas. By performing the above-described trap repairing processes in two operations, the trap repairing of memory cells in the semiconductor component 10 and the trap repairing of the device layer 220 can be improved (e.g., optimized) at the same time, and the storage performance of the semiconductor component 10 can be improved (e.g., maximized) without influencing the reliability of circuits in the device layer 220.

Example implementations of the disclosure provide a semiconductor component. For this semiconductor component, the disclosure provides three implementations, which will be described in detail below respectively.

### Implementation 1

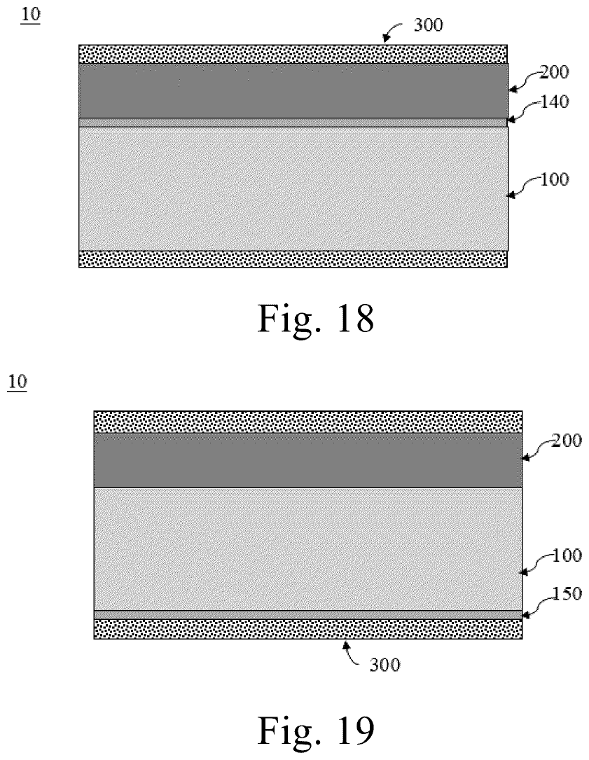

As shown in FIG. 18, the semiconductor component 10 includes the first wafer 100 and the second wafer 200. The first wafer 100 includes memory cells, and the second wafer 200 is bonded with the first wafer 100 to form a bonding interface. The second wafer 200 includes a device layer including, for example, peripheral devices such as transistor devices (CMOS). The first dielectric layer 140 is on the side of the first wafer 100 facing the bonding interface, and a material of the first dielectric layer 140 includes at least one of nitride, polysilicon or carbonitride.

In some example, the thickness of the first dielectric layer 140 may range from 2 μm to 10 μm.

In some examples, the semiconductor component 10 further includes an encapsulation layer 300 located at the sides of the first wafer 100 and the second wafer 200 away from the bonding interface.

### Implementation 2

As shown in FIG. 19, the semiconductor component 10 includes the first wafer 100, the second wafer 200 and the encapsulation layer 300. The first wafer 100 includes memory cells. The second wafer 200 is bonded with the first wafer 100 to form a bonding interface. The second wafer 200 includes a device layer including, for example, peripheral devices as transistor devices (CMOS). The encapsulation layer 300 is located at the sides of the first wafer 100 and the second wafer 200 away from the bonding interface. A second dielectric layer 150 is included between the side of the first wafer 100 away from the second wafer 200 and the encapsulation layer 300, and a material of the second dielectric layer 150 includes at least one of nitride, polysilicon or carbonitride.

In some implementations, the thickness of the second dielectric layer 150 is less than that of the encapsulation layer 300.

In some implementations, the thickness of the second dielectric layer 150 ranges from 1 μm to 5 μm.

### Implementation 3

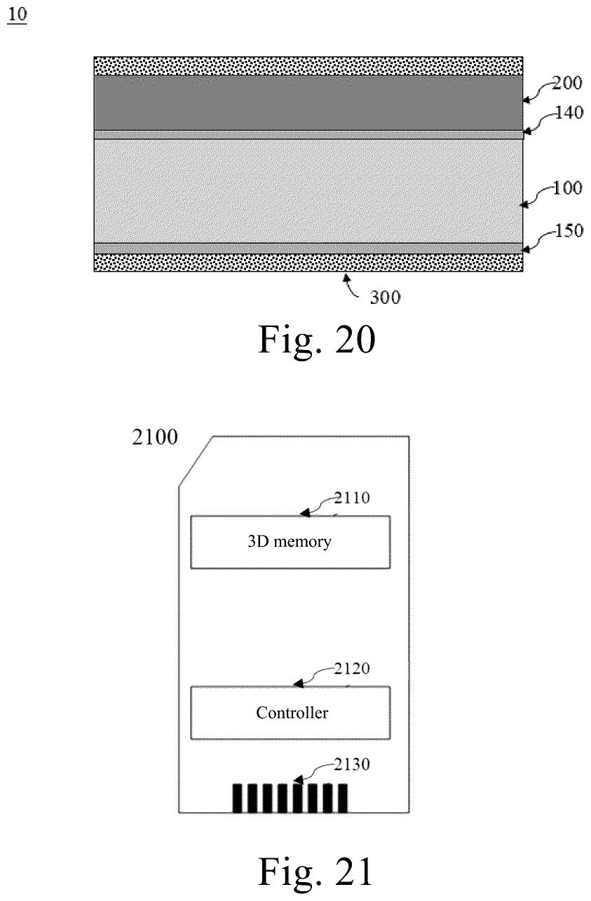

As shown in FIG. 20, the semiconductor component 10 includes the first wafer 100, the second wafer 200 and the encapsulation layer 300. The first wafer 100 includes memory cells. The second wafer 200 is bonded with the first wafer 100 to form a bonding interface. The second wafer 200 includes a device layer including, for example, peripheral devices as transistor devices (CMOS). The encapsulation layer 300 is located at the sides of the first wafer 100 and the second wafer 200 away from the bonding interface. The first dielectric layer 140 is on the side of the first wafer 100 facing the bonding interface, and a material of the first dielectric layer 140 includes at least one of nitride, polysilicon or carbonitride. The second dielectric layer 150 is between the side of the first wafer 100 away from the second wafer 200 and the encapsulation layer 300, and a material of the second dielectric layer 150 includes at least one of nitride, polysilicon or carbonitride.

In some examples, the thickness of the first dielectric layer 140 range from 2 μm to 10 μm. The thickness of the second dielectric layer 150 ranges from 1 μm to 5 μm.

Example implementations in accordance with teachings of the disclosure provide a memory system, including the semiconductor component provided by any of the implementations described above; and a controller electrically connected with and used to control the semiconductor component.

In example methods disclosed herein, the first dielectric layer and/or the second dielectric layer in the semiconductor component be used to repair the traps in the memory cells twice, and the trap repairing process may be performed at a higher temperature before the wafer bonding to repair the traps in the memory cells deeply without damaging the device layer with the high temperature processing, thereby improving storage performance of the memory device.

FIG. 21 is a structural diagram of an example memory system constructed in accordance with teachings of the present disclosure.

As shown in FIG. 21, the memory system 2100 includes a 3D memory 2110 and a controller 2120. The 3D memory 2110 is the semiconductor component 10 as mentioned in above, or at least includes the semiconductor component 10 as discussed in any of the above implementations. The controller 2120 is electrically connected with and used to control the 3D memory 2110.

In the example shown in FIG. 21, the controller 2120 and a single 3D memory 2110 may be integrated into a memory card. The memory card can include a PC card (PCMCIA, personal computer memory card international association), a compact flash (CF) card, a smart media (SM) card, a memory stick, a multimedia card (MMC, RS-MMC, MMCmicro), a SD card (SD, miniSD, microSD, SDHC), a universal flash storage (UFS) card, etc. The memory card can further include a memory card connector 2130 coupling the memory card with a host.

In another example, the controller 2120 and a plurality of 3D memory 2110 can be integrated into a solid state driver (SSD). The SSD can further include a SSD connector 2130 coupling the SSD with a host. In some examples, the storage capacity and/or the operation speed of the SSD is greater than those of the memory card as shown in FIG. 21.

The present disclosure provides semiconductor components, fabrication methods thereof and memory systems to at least partially solve at least one of the above-described problems in related arts.

In some examples, a fabrication method of a semiconductor component, includes: performing trap repairing on a first wafer at a first temperature, the first wafer including memory cells; bonding the first wafer with a second wafer to form the semiconductor component, the second wafer including a device layer; and repairing the semiconductor component at a second temperature lower than the first temperature.

In some examples, performing trap repairing on the first wafer at the first temperature includes: forming a first dielectric layer containing hydrogen bonds on a first or second side of the first wafer, wherein the first side is the side to be bonded with the second wafer and the second side is the other side opposite to the first side; and performing an annealing process at the first temperature to passivate the traps in the memory cells.

In some examples, the fabrication method further includes: after performing trap repairing on the first wafer at the first temperature, forming bonding contacts to be bonded with the second wafer on the first side of the first wafer.

In some examples, the material of the first dielectric layer is at least one of nitride containing hydrogen bonds, polysilicon containing hydrogen bonds and carbonitride containing hydrogen bonds; and the hydrogen content of the first dielectric layer is higher than 1 e21 cm-3.

In some examples, the duration of the annealing process performed at the first temperature ranges from 2 h to 10 h.

In some examples, the first temperature is in the range of 500° C. to 800° C.

In some examples, the fabrication method further includes: before repairing the semiconductor component at the second temperature lower than the first temperature, removing at least a portion of the first dielectric layer.

In some examples, repairing the semiconductor component at the second temperature lower than the first temperature includes: performing the annealing process at the second temperature to repair the semiconductor component.

In some examples, a substrate is disposed on the second side of the first wafer; and the fabrication method further includes: before repairing the semiconductor component at the second temperature lower than the first temperature, removing the substrate. The b repairing of the semiconductor component at the second temperature lower than the first temperature includes: forming a second dielectric layer containing hydrogen bonds on the second side of the first wafer; and performing the annealing process at the second temperature to repair the traps in the semiconductor component.

In some examples, the thickness of the second dielectric layer is less than that of the first dielectric layer.

In some examples, the second temperature is in the range of 400° C. to 450° C.

Some example semiconductor components include: a first wafer including memory cells; and a second wafer bonded with the first wafer to form a bonding interface, the second wafer including a device layer. A first dielectric layer is on the side of the first wafer facing the bonding interface, and a material of the first dielectric layer including at least one of nitride, polysilicon or carbonitride.

In some examples, the thickness of the first dielectric layer is in the range of 2 μm to 10 μm

In some examples, the semiconductor component includes: an encapsulation layer on the sides of the first wafer and the second wafer away from the bonding interface

In some examples, the semiconductor component further includes: a second dielectric layer between the side of the first wafer away from the second wafer and the encapsulation layer, a material of the second dielectric layer including at least one of nitride, polysilicon or carbonitride.

Example semiconductor components disclosed herein include: a first wafer including memory cells; a second wafer bonded with the first wafer to form a bonding interface, the second wafer including a device layer, and an encapsulation layer on the sides of the first wafer and the second wafer away from the bonding interface; wherein a second dielectric layer is included between the side of the first wafer away from the second wafer and the encapsulation layer, and a material of the second dielectric layer includes at least one of nitride, polysilicon or carbonitride.

In some examples, the thickness of the second dielectric layer is less than that of the encapsulation layer.

In some examples, the thickness of the second dielectric layer is in the range of 1 μm to 5 μm.

In some examples, the semiconductor component includes: a first dielectric layer on the side of the first wafer facing the bonding interface, a material of the first dielectric layer including at least one of nitride, polysilicon or carbonitride.

Example memory systems disclosed herein, include: a semiconductor component as disclosed above; and a controller electrically connected with and used to control the semiconductor component.

In some example fabrication methods disclosed herein, the traps in the memory cells are repaired twice and the trap repairing process is performed at a higher temperature before wafer bonding to thereby repair deep traps in the memory cells without causing damage to the device layer which might otherwise be caused by the application of the high temperature processing, thereby improving storage performance of the resulting memory device.

The description above is only for the purpose of illustrating teachings of the present disclosure and the technical principles they used. It will be appreciated by those skilled in the art that the scope of the appended claims are not limited to the above illustrations or the above discussed technical solutions or particular combinations thereof, and instead cover many other technical solutions including, for example, combinations of the above-mentioned features and their equivalents without departing from scope and spirit of this disclosure, For example, technical solutions resulting from substitutions of the above-described features by technical features of similar functions fall within the scope of the present disclosure.

We claim:

1. A method of fabricating a semiconductor component, the method comprising:
performing trap repairing on a first wafer at a first temperature, the first wafer including memory cells;
bonding the first wafer with a second wafer to form the semiconductor component, the second wafer including a device layer; and
repairing the semiconductor component at a second temperature lower than the first temperature.

2. The method of claim 1, wherein the performing of the trap repairing on the first wafer at the first temperature comprises:
forming a first dielectric layer containing hydrogen bonds on a first side or a second side of the first wafer, wherein the first side is the side to be bonded with the second wafer, and the second side is the other side opposite to the first side; and
performing an annealing process at the first temperature to passivate the traps in the memory cells.

3. The method of claim 2, further comprising: after the performing of the trap repairing on the first wafer at the first temperature, forming bonding contacts to be bonded with the second wafer on the first side of the first wafer.

4. The method of claim 2, wherein a material of the first dielectric layer is at least one of nitride containing hydrogen bonds, polysilicon containing hydrogen bonds or carbonitride containing hydrogen bonds; and
the hydrogen content of the first dielectric layer is higher than 1 e21 cm⁻³.

5. The method of claim 2, wherein the duration of the annealing process performed at the first temperature ranges from 2 h to 10 h.

6. The method of claim 1, wherein the first temperature is in the range of 500° C. to 800° C.

7. The method of claim 2, further comprising, before repairing the semiconductor component at the second temperature lower than the first temperature, removing at least a portion of the first dielectric layer.

8. The method of claim 2, wherein the repairing of the semiconductor component at the second temperature lower than the first temperature includes: performing the annealing process at the second temperature to repair the semiconductor component.

9. The method of claim 2, wherein a substrate is on the second side of the first wafer and the fabrication method comprises, before repairing the semiconductor component at the second temperature lower than the first temperature:
removing the substrate; and
wherein the repairing of the semiconductor component at the second temperature lower than the first temperature includes:
forming a second dielectric layer containing hydrogen bonds on the second side of the first wafer; and
performing the annealing process at the second temperature to repair the traps in the semiconductor component.

10. The method of claim 9, wherein the thickness of the second dielectric layer is less than that of the first dielectric layer.

11. The method of claim 1, wherein the second temperature is in the range of 400° C. to 450° C.

12. A semiconductor component, comprising:
a first wafer including memory cells; and
a second wafer bonded with the first wafer to form a bonding interface, the second wafer including a device layer;
wherein a first dielectric layer is on the side of the first wafer facing the bonding interface, and a material of the first dielectric layer includes at least one of nitride, polysilicon or carbonitride.

13. The semiconductor component of claim 12, wherein
the thickness of the first dielectric layer is in the range of 2 μm to 10 μm.

14. The semiconductor component of claim 12, further comprising:
an encapsulation layer on the sides of the first wafer and the second wafer away from the bonding interface.

15. The semiconductor component of claim 14, further comprising:
a second dielectric layer between the side of the first wafer away from the second wafer and the encapsulation layer, a material of the second dielectric layer including at least one of nitride, polysilicon or carbonitride.

16. The semiconductor component of claim 15, wherein the thickness of the second dielectric layer is less than that of the encapsulation layer.

17. The semiconductor component of claim 15, wherein the thickness of the second dielectric layer is in the range of 1 μm to 5 μm.

18. A memory system, comprising:
a semiconductor component including:
a first wafer including memory cells; and
a second wafer bonded with the first wafer to form a bonding interface, the second wafer including a device layer, wherein a first dielectric layer is on the side of the first wafer facing the bonding interface, and a material of the first dielectric layer includes at least one of nitride, polysilicon or carbonitride; and
a controller to control the semiconductor component.
